(19) United States
(12) Patent Application Publication
(10) Pub. No.: US 2026/0254354 A1
(43) Pub. Date: Aug. 27, 2026

(54) Switched-Capacitor DC-DC Power Converter with Segmented Switches

(71) Applicant: Skycore ApS, Copenhagen Ø (DK)

(72) Inventors: Dennis Øland Larsen, København Ø (DK); Pere Llimós Muntal, København Ø (DK); Thomas Pierre Marie Souvignet, København Ø (DK); Guifré Vendrell Pausas, København Ø (DK)

(21) Appl. No.: 18/995,398

(22) PCT Filed: Jul. 4, 2023
(86) PCT No.: PCT/EP2023/068346

§ 371 Date: Jan. 16, 2025

(30) Foreign Application Priority Data
Jul. 19, 2022 (EP) 22185684.2

(51) Int. Cl. H02M 3/07; H02M 1/00; H02M 1/36; H02M 3/158

(52) U.S. Cl. CPC H02M 3/07; H02M 1/0095; H02M 1/36; H02M 3/158

(57) ABSTRACT

The disclosure relates to a switched-capacitor DC-DC converter comprising at least one input terminal, at least one output terminal, a plurality of power switches and a plurality of flying capacitors configured to convert a DC input voltage from the at least one input terminal to a DC output voltage to the at least one output terminal by a switched-capacitor power conversion, wherein at least one of the plurality of power switches is a segmented switch, comprising at least one internal switch-segment disposed on a first semiconductor die and at least one external switch-segment disposed on a second semiconductor die and a plurality of gate drivers configured to drive the plurality of power switches. A programmable switch array for a switched-capacitor DC-DC converter and a method for performing a switched-capacitor DC-DC conversion are also disclosed.

The present disclosure relates to a high-voltage switched-capacitor converter comprising segmented switches. The disclosure further relates to a programmable switch array for switched-capacitor DC-DC converter and to a method for performing a switched-capacitor DC-DC conversion.

### BACKGROUND

Segmentation of a power stage of a switched-capacitor DC-DC converter by using several transistors is sometimes used for voltage regulation and to reduce peak currents in relatively simple charge pump integrated circuits. The cost of segmenting a power stage in a low-voltage switched-capacitor DC-DC converter, or more generally in charge pumps, is relatively low, as the power stage driver design is relatively straightforward. Since the gate drivers constituting the power stage driver are not floating relative to the source potential of the transistors constituting the switches of the power stage, there is little or no added cost of splitting the transistors of the power stage in smaller sub-segments. However, in switched-capacitor DC-DC converters used in high-voltage, high-power applications, the power stage is implemented using discrete components, such as individually packaged transistors, level shifters and/or gate drivers. Then the cost of segmenting the power stage is higher as each sub-segment requires separately packaged level shifters and gate drivers.

Additionally, starting up a high-voltage, high-power switched-capacitor DC-DC converter gives rise to large transient currents, which can reduce the switched-capacitor DC-DC converter reliability and lifetime, or even in some cases, be destructive. Existing solutions to this problem include various types of separate pre-charge circuits or additional transistors coupled in series with the power stage. The addition of series transistors for limiting the large transient currents or inrush currents leads to lower performance of the switched-capacitor DC-DC converter once it is out from the startup mode. It is worth noting that input surge current or inrush current is a term inherited from inductor-based boost converters and it mostly applies to simple charge pumps, which are based on a single flying capacitor, as the single problematic current loop for starting up such a converter is in series with the input or output terminal.

It would be beneficial to be able to provide an efficient switched-capacitor DC-DC solution that can be used for loads requiring a higher power. Thus, there exists a need for providing a switched-capacitor DC-DC converter with an efficient way of starting-up the power stage when high output power is needed, and where high electron mobility transistors (HEMT) can be implemented as switches to sustain high-power applications without increasing cost of the implementation as well as its complexity.

### SUMMARY

The present disclosure relates to a switched-capacitor DC-DC converter comprising at least one input terminal, at least one output terminal, a plurality of power switches and a plurality of flying capacitors configured to convert a DC input voltage from the at least one input terminal to a DC output voltage to the at least one output terminal by a switched-capacitor power conversion, wherein at least one of the plurality of power switches is a segmented switch, comprising at least one internal switch-segment disposed on a first semiconductor die of a first semiconductor manufacturing technology and at least one external switch-segment disposed on a second semiconductor die of a second semiconductor manufacturing technology different to the first semiconductor manufacturing technology, and a plurality of gate drivers configured to drive the plurality of power switches.

Gallium nitride (GaN) transistors are very power efficient switches. Unfortunately, their monolithic implementation with low-power digital blocks, such as clock generators and serial communication interfaces, which are mainly designed with silicon (Si) transistors, is relatively complex. Solutions exist to implement both technologies on the same die, but these are rather complex, inefficient or costly. By having at least one of the plurality of power switches disposed on a first semiconductor die and at least one external switch-segment disposed on a second semiconductor die, while having the plurality of gate drivers configured to drive the plurality of power switches, a power efficient switched-capacitor DC-DC converter implementation is achieved. Being able to drive the at least one external switch-segment with the plurality of gate drivers allows the switched-capacitor DC-DC converter to comprise power transistors optimized for high channel conductance, such as high electron mobility transistors or GaN transistors, used as power switches, without having to implement them in silicon on the first semiconductor die.

The at least one of the plurality of power switches is a segmented switch. This provides a solution for limiting the inrush current during a switched-capacitor DC-DC converter startup. This is especially an issue in switched-capacitor DC-DC converters that can deliver high current at the at least one output terminal as the low channel resistance of the plurality of power switches creates low-resistance paths and consequently high peak currents when the plurality of flying capacitors are initially charged during startup.

The disclosure further relates to a programmable switch array for a switched-capacitor DC-DC converter, comprising at least one input terminal, at least one output terminal, a plurality of power switches and a plurality of flying capacitor terminals connectable to a plurality of flying capacitors configured to convert a DC input voltage from the at least one input terminal to a DC output voltage to the at least one output terminal by a switched-capacitor power conversion, wherein at least one of the plurality of power switches is a segmented switch, comprising at least one internal switch-segment disposed on a first semiconductor die of a first semiconductor manufacturing technology, and at least one switch-segment terminal connectable to at least one external switch-segment disposed on a second semiconductor die of a second semiconductor manufacturing technology different to the first semiconductor manufacturing technology, and a plurality of gate drivers configured to drive the plurality of power switches.

A method for performing a switched-capacitor DC-DC conversion is also disclosed, the method comprising the steps of providing a switched-capacitor DC-DC converter comprising at least one input terminal, at least one output terminal, a plurality of power switches and a plurality of flying capacitors configured to convert a DC input voltage from the at least one input terminal to a DC output voltage to the at least one output terminal by a switched-capacitor power conversion, wherein at least one of the plurality of power switches is a segmented switch, comprising at least one internal switch-segment disposed on a first semiconductor die of a first semiconductor manufacturing technology and at least one external switch-segment disposed on a second semiconductor die of a second semiconductor manufacturing technology different to the first semiconductor manufacturing technology, a plurality of gate drivers configured to drive the plurality of power switches, and performing a switched-capacitor DC-DC conversion by switching the plurality of power switches, using the at least one internal switch-segment and the at least one external switch-segment in order to convert a DC input voltage to a DC output voltage.

As it would be understood by a person skilled in the art, the presently disclosed method for performing a switched-capacitor DC-DC conversion may be performed using any embodiment of the presently disclosed switched-capacitor DC-DC converter or programmable switch array for switched-capacitor DC-DC converter, and vice versa.

### DESCRIPTION OF THE DRAWINGS

In the following embodiment and examples will be described in greater detail with reference to the accompanying drawings. The drawings are examples of embodiments and not limiting to the presently disclosed switched-capacitor DC-DC converter and method for performing a switched-capacitor DC-DC conversion.

FIG. 1 shows a schematic view of an embodiment of a switched-capacitor DC-DC converter,

FIG. 2 shows a schematic view of an embodiment of a switched-capacitor DC-DC converter comprising at least one external switch-segment,

FIG. 3A-D show an embodiment of some possible implementations of the plurality of flying capacitors and the plurality of power switches to perform a switched-capacitor DC-DC conversion,

FIG. 4 shows a schematic view of an embodiment of one of the plurality of power switches,

FIG. 5 shows a schematic view of an embodiment of one of the plurality of gate drivers,

FIG. 6 shows a schematic view of an embodiment of a programmable switch array for switched-capacitor DC-DC converter,

FIG. 7 shows a flow-chart of the presently disclosed method of performing a switched-capacitor DC-DC conversion.

### DETAILED DESCRIPTION

The present disclosure relates to a DC-DC converter comprising a plurality of power switches and a plurality of flying capacitors configured to convert a DC input voltage to a DC output voltage by a power conversion, wherein at least one of the plurality of power switches is a segmented switch.

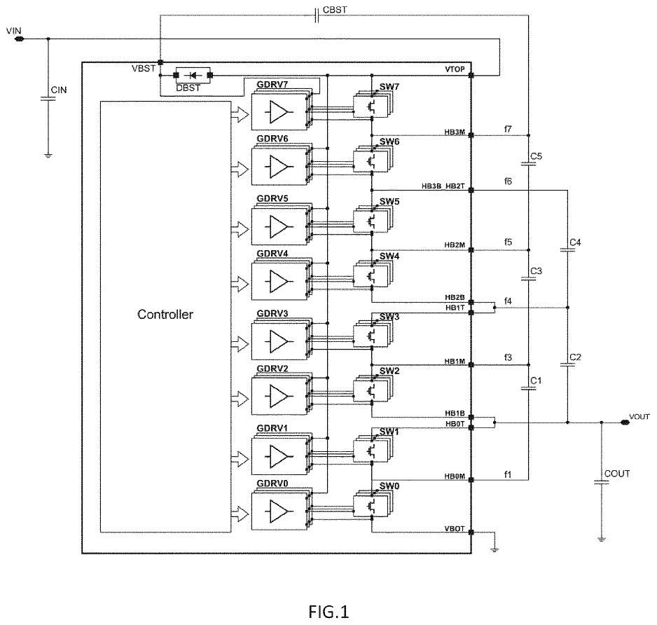

FIG. 1 shows a schematic view of an embodiment of a switched-capacitor DC-DC converter. The switched-capacitor DC-DC converter comprises at least one input terminal, at least one output terminal, a plurality of power switches and a plurality of flying capacitors. The at least one input terminal is named VIN, which corresponds to the DC input voltage of the switched-capacitor DC-DC converter, and the at least one output terminal is named VOUT, which corresponds to the DC output voltage of the switched-capacitor DC-DC converter. The switched-capacitor DC-DC converter further comprises a plurality of gate drivers, such as GDRV0-GDRV7, which are configured to independently drive the plurality of power switches, such as SW0-SW7. In the example of FIG. 1, the flying capacitors, namely C1, C2, C3, C4 and C5, are configured with the plurality of power switches in a Ladder 1/4 configuration. This specific configuration gives a voltage ratio of 4 between the DC input voltage and the DC output voltage, and wherein the DC output voltage is lower than the DC input voltage. The power switches are segmented in 3 switch-segments, wherein the 3 switch-segments are comprised in the same semiconductor die as the other elements comprised in the switched-capacitor DC-DC converter. Each switch-segment is directly driven by its associated and unique gate driver. Each of the plurality of gate drivers receives an independent control signal from a control unit, named “Controller” in FIG. 1. This independent control signal can be a clock signal. It is buffered by the plurality of gate drivers and then potentially reshaped. The independent control signal may be sent to the plurality of power switches, in order to control their switching states. As shown in FIG. 1, a bootstrap circuit is implemented to provide a boosted voltage for the top-most gate driver GDRV7. The bootstrap circuit comprises a bootstrap capacitor, named CBST, and a bootstrap diode, DBST. The top-most gate driver, GDRV7, may require a positive supply voltage, which cannot be provided by connecting the GDRV7 positive supply terminal to VTOP and the GDRV7 negative supply terminal to the source terminal of SW7 as the voltage from VTOP to the source of SW7 is approximately zero when SW7 is conducting. The bootstrap diode may provide a charging path from VTOP to the CBST boost capacitor when SW7 is opened (OFF) and the diode is blocking when SW7 is closed (ON). The result of the bootstrap circuit operation is a stable supply voltage for GDRV7 relative to the GDRV7 negative supply terminal, which is connected to the source terminal of SW7. A decoupling capacitor COUT is connected to the at least one output terminal to filter the DC output voltage of the switched-capacitor DC-DC converter and a decoupling capacitor CIN is connected to the at least one input terminal to filter the DC input voltage of the switched-capacitor DC-DC converter.

The switched-capacitor DC-DC converter as shown in FIG. 1 can also be configured for a switched-capacitor DC-DC step-up conversion. In this specific configuration, the DC input voltage is VOUT and the DC output voltage is VIN. This gives a voltage ratio of 4 between the DC input voltage and the DC output voltage, and wherein the DC output voltage is higher than the DC input voltage.

A flying capacitor can be a capacitor used for, either directly or indirectly, transferring charge from the at least one input terminal to the at least one output terminal. The flying capacitor may be periodically charged and discharged by means of the plurality of power switches providing charging and discharging paths as defined by the switched-capacitor DC-DC converter topology or configuration. A flying capacitor may be defined as “flying” in the sense that the common-mode voltage, i.e. the average voltage between the two capacitor terminals, has a square waveform relative to the ground voltage. This is for example the case of the flying capacitors in a switched-capacitor DC-DC converter with a Dickson topology. However, a flying capacitor can also have a stable common-mode voltage such as in a ladder converter where some of the flying capacitors are used to decouple the intermediate voltages at nominal voltage levels that are integer fractions of the input voltage. The flying capacitors are different from decoupling capacitors, which are typically placed close to the converter input and output terminals to reduce the voltage swing at these voltage nodes. Removing a decoupling capacitor does not significantly reduce the DC-DC converter's capability of converting power, whereas removing a flying capacitor will substantially render the DC-DC converter incapable of converting power.

The segmentation of the power switches may allow a safe start-up of the switched-capacitor DC-DC converter, by possibly limiting an inrush current, said inrush current due to the presence of multiple low impedance loops in the switched-capacitor DC-DC converter. Secondly, the segmentation of the power switches can allow a system or a user to enable only some of the switch-segments, therefore limiting the power consumption of the switched-capacitor DC-DC converter by potentially reducing the parasitic losses arising from charging and discharging the plurality of parasitic capacitances. Only a few switch-segments may be needed if the output load requires a small current as the few switch-segments conduction losses may be small compared with the parasitic losses. For instance, in a case where the switched-capacitor DC-DC converter is supplying a CPU, if the CPU is in throttled mode, it does not require as much current as when it may be configured in a normal mode, where more current can be desired. The segmentation of the power switches may help to reduce electromagnetic interference by reducing the voltage rise and fall time,

$$\frac{dv}{dt} ,$$

of the nodes between the plurality of power switches during phase transitions. A switched-capacitor DC-DC converter may operate in at least two states, wherein each state can represent a unique connection of the flying capacitor and power converter terminals. These states may be configured by the clock signals that drive each of the plurality of power switches. These clock signals may have a 180 degree phase shift and can be non-overlapping with a deadtime between each of the clock signals. When the switched-capacitor DC-DC converter transition from one switching state to the next switching state, the internal nodes between the plurality of power switches may produce large voltage transitions as the plurality of flying capacitors can interact differently between them in each state. The rise and fall times of these voltage transitions are a function of the parasitic capacitances present in the internal nodes between the plurality of power switches, and the conductance of the plurality of power switches. The plurality of flying capacitors may experience only a small voltage ripple whereas the internal nodes between the plurality of power switches can experience a large voltage swing. Switching large power transistors, especially HEMTs, such as GaN FETs, may lead to very rapid charging and discharging of the parasitic capacitances in the plurality of power switches. This high

$$\frac{dv}{dt}$$

can generate electromagnetic interference and can create kickback in one or more of the plurality of power switches that are opened (OFF), through the gate-drain capacitance of the power transistor. The kickback may create a positive gate-source voltage (Vgs) spur, preferably for NMOS devices, which can create cross-conduction if the Vgs spur approaches or exceeds the device threshold voltage. The kickback issue may preferably be solved by very complex gate driver systems that may provide negative Vgs when the switch is opened (OFF) in order to have a large margin from the threshold voltage to accommodate the Vgs kickback spur. The

$$\frac{dv}{dt}$$

can be reduced by only closing (turning ON) the smallest switch-segment during e.g. the first 10 ns of a converter state. This ensures that the parasitic capacitors are charged and/or discharged using the relatively small conductance switch-segments and the result can be a lower

$$\frac{dv}{dt} .$$

The lower

$$\frac{dv}{dt}$$

may allow for using a relatively simpler gate driver structure that does not provide negative Vgs in the opened (OFF) state. After the e.g. 10 ns delay, the other switch-segments can be delayed, potentially in a time-staggered fashion. This 10 ns delay may be a small part of the total state duration, which is e.g. approximately 500 ns in a 1 MHz two-state topology, such as the Dickson 1/4.

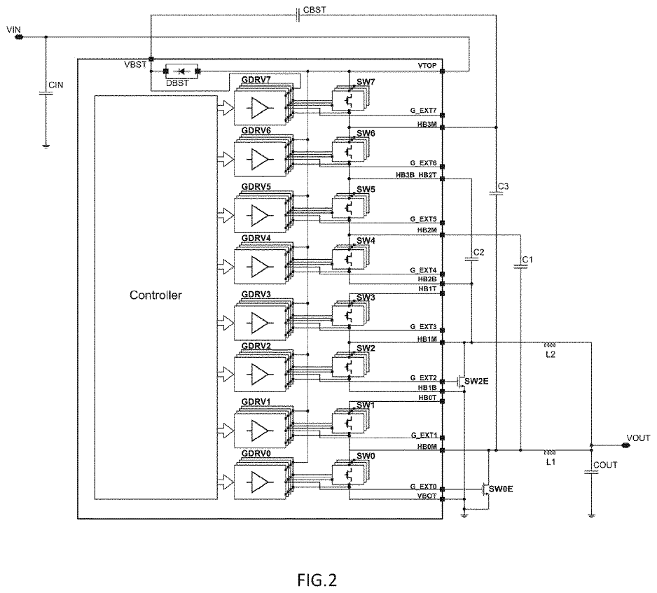

FIG. 2 shows an example of a schematic view of an embodiment of a switched-capacitor DC-DC converter, wherein the plurality of power switches is a segmented switch, but where at least one switch-segment is an external switch-segment, which is disposed on a second semiconductor die. The at least one input terminal is named VIN, which corresponds to the DC input voltage of the switched-capacitor DC-DC converter, and the at least one output terminal is named VOUT, which corresponds to the DC output voltage of the switched-capacitor DC-DC converter. The switched-capacitor DC-DC converter further comprises a plurality of gate drivers, such as GDRV0-GDRV7, which are configured to independently drive the plurality of power switches, such as SW0-SW7, as well as SW0E and SW2E. As stated above, according to a first embodiment of the presently disclosed switched-capacitor DC-DC converter, at least one internal switch-segment is disposed on a first semiconductor die and at least one external switch-segment disposed on a second semiconductor die. As it is shown in the example of FIG. 2, two switch-segments are external, namely SW0E and SW2E. It would be possible to have, as a minimum one external switch-segment disposed on the second semiconductor die. Each of the two switch-segments in FIG. 1 is an external switch-segment of one of the plurality of the power switches. For instance, SW0E is an external switch-segment of SW0. They are connected in parallel through the terminals VBOT and HB0M. The external switch-segment SW0E is driven by one of the gate drivers GDRV0, through the terminal G_EXT0. The same procedure is applied to the other external switch-segment, SW2E. By having the option of implementing one of the switch-segments externally, this gives a possibility of having this external switch-segment configured with different characteristics than the internal switch-segments in order to enable more power, potentially less noise, and some other advantages inherent to a specific external switch-segment technology. As shown in FIG. 2, two inductors, namely L1 and L2, are connected to the output terminal VOUT. This enables a hybrid configuration of a switched-capacitor DC-DC converter. This hybrid configuration may add some benefits to a switched-capacitor DC-DC converter without inductors. Hybrid switched-capacitor converters can be categorized as resonant or soft-charged depending on where the at least one inductor is placed. Adding the at least one inductor in series with one or more of the plurality of flying capacitors creates a resonant topology. Adding the at least one inductor with an inductor terminal connected to a converter input, output, ground/reference terminal, or an intermediate DC bus, creates a soft-charged converter. In a resonant switched-capacitor DC-DC converter, an inductor is added in series with at least one flying capacitor to create a resonant LC tank that has a low impedance at a given resonant frequency. The inductor will have zero DC current as it is connected in series with one or more capacitors. This resonant configuration allows for using smaller capacitors in conjunction with one or more inductors. Depending on the available capacitor and inductor technologies for implementing the converter's passive components, it might in some cases be beneficial to use resonant topologies, such as the switched tank converter, to achieve a certain converter performance with a combination of inductors and capacitors instead of only capacitors. Furthermore, resonant switched-capacitor power converters have approximately sinusoidal current and voltage waveforms, which have lower high-frequency spectral energy compared with the approximately square-wave waveforms of switched capacitor power converters without inductors. This can be beneficial in some applications, however this benefit is a tradeoff with the larger radiated magnetic field from the inductor, which is not an issue in switched capacitor power converters without inductors. A bootstrap circuit is implemented to provide a boosted voltage for the top-most gate driver GDRV7. The bootstrap circuit comprises a bootstrap capacitor, named CBST, and a bootstrap diode, DBST. The top-most gate driver, GDRV7, may require a positive supply voltage, which cannot be provided by connecting the GDRV7 positive supply terminal to VTOP and the GDRV7 negative supply terminal to the source terminal of SW7 as the voltage from VTOP to the source of SW7 is approximately zero when SW7 is conducting. The bootstrap diode may provide a charging path from VTOP to the CBST boost capacitor when SW7 is opened (OFF) and the diode is blocking when SW7 is closed (ON). The result of the bootstrap circuit operation is a stable supply voltage for GDRV7 relative to the GDRV7 negative supply terminal, which is connected to the source terminal of SW7. A decoupling capacitor COUT is connected to the at least one output terminal to filter the DC output voltage of the switched-capacitor DC-DC converter and a decoupling capacitor CIN is connected to the at least one input terminal to filter the DC input voltage of the switched-capacitor DC-DC converter.

The presently disclosed switched-capacitor DC-DC converter may be configured to have a DC input voltage between 12 and 400 V, preferably between 36 and 60 V. It can be configured for stepped-up and stepped-down power conversions, wherein the DC input voltage can be lower or higher than the DC output voltage, with many possible power conversion ratios, depending on the configuration of the power switches together with the flying capacitors. The architecture of the plurality of power switches may allow a system or a user to use a large range of DC input voltage.

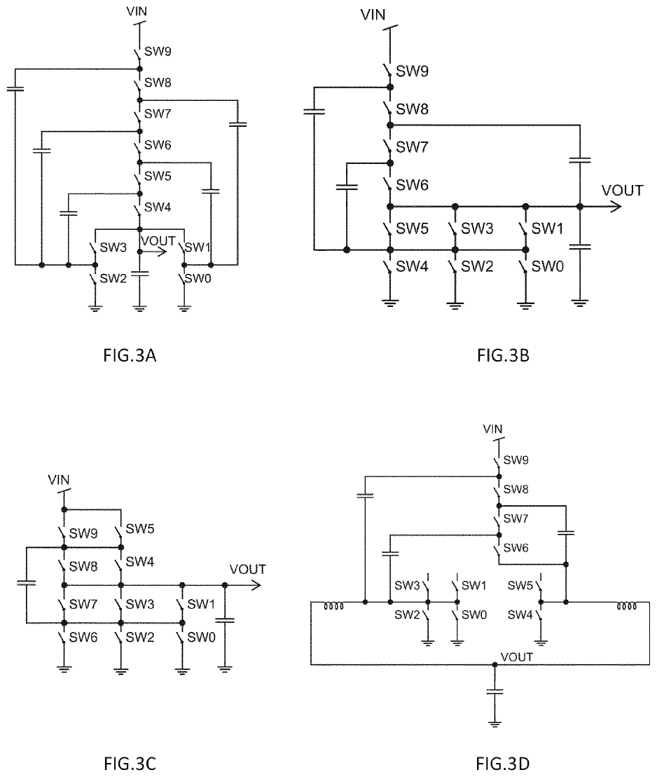

The plurality of power switches and the plurality of flying capacitors can be configured to perform a variety of power conversion such as a Dickson-type power conversion, such as Dickson 1/4 or a Dickson 1/6. Other variants of power conversion can also be performed such as a Ladder 1/3, a Divider 1/2 or a Ladder 1/5. Furthermore, Cockroft-Walton, series-parallel, fractional, exponential, and Pelliconi type power conversion may also be performed. FIG. 3A-D show an embodiment of some possible implementations of the plurality of flying capacitors and the plurality of power switches.

The different switched-capacitor DC-DC converter configurations, such as Dickson, ladder, Cockroft-Walton, series-parallel, fractional, exponential, or Pelliconi have different inherent performance characteristics. A switched-capacitor DC-DC converter configuration can have an inherent ideal voltage conversion ratio, which is the ratio between the DC output voltage to the DC input voltage that the converter may approach when no load current is drawn from the switched-capacitor DC-DC converter. Generally, several different configurations can be used to implement a given ideal voltage conversion ratio, such as 1/3, 1/4, 2/5 or 1/6. For a given ideal voltage conversion ratio, each configuration can define different ways of connecting the plurality of power switches and the plurality of flying capacitors. These components in each configuration can have different charge flow vectors. The charge flow vectors may define how much current is flowing through each of these components. A tradeoff can be made between the plurality of power switches and the plurality of flying capacitor sizes to optimize the efficiency by minimizing the power losses. Some configurations make better use of the plurality of flying capacitors, such as the series-parallel configuration, and some configurations make better use of the plurality of power switches, such as the Dickson configuration. Additionally, each configuration can require different voltage ratings of each of the plurality of power switches, which has to be considered together with the available devices in the semiconductor process used to implement the plurality of power switches. Furthermore, the different configurations may have different voltage swings in the internal nodes of the power stage. Depending on the relative parasitic capacitances of the plurality of power switches, the plurality of flying capacitors and/or the load current, a configuration may be preferred over another to minimize the parasitic capacitance losses.

FIG. 3A shows a Dickson 1/6 configuration, which is a step-down power converter with a ratio of 6 between the DC input voltage and the DC output voltage, and where the DC output voltage is lower than the DC input voltage. This configuration comprises 10 switches and 5 flying capacitors. FIG. 3B shows a Ladder 1/3 configuration, which is a step-down power converter with a ratio of 3 between the DC input voltage and the DC output voltage, and where the DC output voltage is lower than the DC input voltage. This configuration comprises 10 switches and 3 flying capacitors. FIG. 3C shows a Divider 1/2 configuration, which is a step-down power converter with a ratio of 2 between the DC input voltage and the DC output voltage, and where the DC output voltage is lower than the DC input voltage. This configuration comprises 10 switches and one flying capacitor. FIG. 3D shows a Dual Inductor Hybrid Converter (DIHC) 1/4 configuration, which is a step-down power converter with a variable voltage conversion ratio, having a minimum ratio of 4 between the DC input voltage and the DC output voltage, and where the DC output voltage is lower than the DC input voltage. This configuration comprises 10 switches, three flying capacitors and two inductors. These different possible configurations of the switched-capacitor DC-DC converter may affect the power conversion ratio between the input voltage and the output voltage. The hybrid configuration of a switched-capacitor DC-DC converter such as the one shown in FIG. 3D may have the benefits of counteracting the potential drawbacks of a capacitor-based only switched-capacitor DC-DC converter, while improving the performances of classical inductor-based DC-DC converter such as buck or boost power converters. Indeed, the traditional inductor-based buck converter requires a bulky inductor and switches rated for the full input voltage and the full output current of the required application. When dealing with high power densities, low-loss inductors may be difficult to integrate. In contrast to an inductor-based buck or boost converter, a switched-capacitor DC-DC converter requires only capacitors, which can have a significantly higher power density.

In order to perform a power conversion, the switched-capacitor DC-DC converter may need to open and close the plurality of power switches within a specific period of time, and each of the power switches may have different time of opening and closing state. In this context, the plurality of power switches can be independently controlled by a plurality of gate drivers. Each gate drivers may be configured to control the state of the power switches, such as an open or a close state of the power switches. Each of the internal and/or external switch-segments can be individually and/or independently controlled by the plurality of gate drivers. The output impedance of the plurality of gate drivers can be configured to drive the plurality of power switches with the correct impedance matching, depending on the desired application.

The internal and/or external switch-segments comprised in each of the plurality of power switches may be connected in parallel, as it is shown in FIG. 2. Since they are independently controlled by the plurality of gate drivers, they can be independently switched, depending on the switched-capacitor DC-DC converter configuration needed and the switched-capacitor DC-DC converter output load.

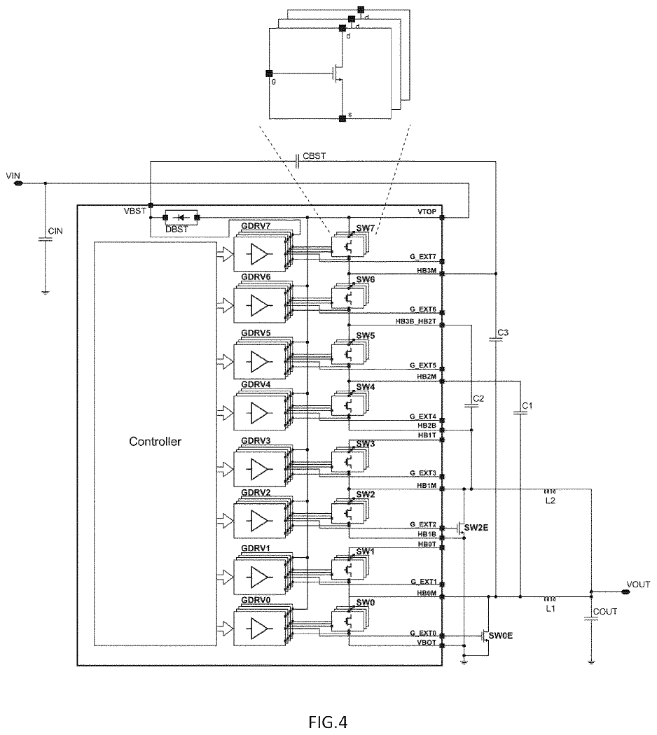

Each of the plurality of power switches may comprise a positive terminal and a negative terminal, such as a drain and a source terminal, respectively. FIG. 4 shows a schematic view of an embodiment of a power switch. The power switch has three switch-segments, connected in parallel. The three switch-segments have 3 terminals, namely “g”, “s” and “d”. “g” may stand for “gate”, “d” can stand for “drain” while “s” may potentially stand for “source”.

Each of the internal switch-segments can comprise a field-effect transistor, preferably a metal-oxide-semiconductor field-effect transistor (MOSFET). Metal-oxide-semiconductor field-effect transistor is a type of insulated-gate field-effect transistor that is fabricated by the controlled oxidation of a semiconductor, typically silicon. The voltage applied on the gate determines the electrical conductivity of the device. This ability to change conductivity with the amount of applied voltage can be used for switching electronic signals. This is one of the reason it may be used as a power switch, since the gate of the MOSFET can be driven by a gate driver, therefore changing the state of the switch.

In one embodiment, the internal switch-segments do not comprise stacked or cascaded field-effect transistors. Indeed, at least one of the field-effect transistor may be a power MOSFET device, such as a laterally double diffused metal oxide semiconductor (LDMOS) or a super junction double diffused metal oxide semiconductor (SJ-LDMOS). The power MOSFETs can sustain a relatively high voltage, preferably comprised between 10 to 500 V. In this context, the power MOSFETs can sustain the maximum value of the possible DC input voltage of the presently disclosed switched-capacitor DC-DC converter. The field-effect transistors may be N-type transistors, such as N-channel MOSFETs. They can be asymmetrical transistors types, wherein a maximum drain-source voltage (Vds) is higher than the maximum gate-source voltage (Vgs). Asymmetrical transistors types can allow a very large drain-source voltage, while being driven with a lower voltage on the gate to allow a switching between on and off states. It may make them suitable for high-voltage, high-power switched-capacitor DC-DC converter applications.

The at least one internal switch-segment may be implemented on a silicon substrate. A silicon substrate can also be called a silicon wafer, which is a thin slice of semiconductor, used for the fabrication of integrated circuits. Other types of substrates may be used, such as III-V or II-VI materials, such as gallium arsenide (GaAs), gallium nitride (GaN) or silicon carbide (SiC). Silicon may be preferred for the at least one internal switch-segment because of its relatively low cost compared to other materials.

At least one external switch-segment may be a vertical MOSFET optimized for low channel conductance. By using a vertical structure, it can be possible for the transistor to sustain both high blocking voltage and high current. The vertical MOSFET typically cannot be fabricated on the first semiconductor die where planar devices are implemented, preferably optimized for low-power circuits. Therefore the at least one external switch-segment can be implemented on a second semiconductor die.

At least one external switch-segment may be a high-electron-mobility transistor (HEMT). HEMT is a field-effect transistor incorporating a junction between two materials with different band gaps as the channel instead of a doped region. One material combination can be used, such as Gallium Nitride (GaN), in order to obtain GaN-based HEMTs. Other material combination is GaAs with AlGaAs, though there is a wide variation, dependent on the application. The advantages of HEMTs are the possible high gain, high switching speeds and extremely low channel resistance. They may have the disadvantage of being quite expensive compared to MOSFETs. By having the option of implementing at least one external switch-segment as a HEMT, this gives the possibility of driving larger output loads requiring more current for a given DC output voltage, and potentially lower the switching losses of the switched-capacitor DC-DC converter.

The first semiconductor die can be optimized for implementing advanced analog and digital circuitry, such as level-shifters, gate drivers, clock generation circuits, clock controllers, linear voltage regulators or temperature sensors. Semiconductor processes optimized for advanced analog and digital circuitry may require more processing steps and photomasks to implement a wider selection of electronic components. In order to support the possible wider selection of electronic components, tradeoffs must be made in the semiconductor material features that might decrease the performance of power transistors implemented using the same semiconductor process.

In one embodiment, the plurality of gate drivers are disposed on the first semiconductor die. The plurality of gate drivers may be designed with semiconductor processes that can be optimized for low power consumption and high integration density. The plurality of gate drivers may also be designed and implemented on semiconductor processes optimized for power transistor implementation if a relatively low conductance can be desired at the output of the plurality of gate drivers.

The second semiconductor die can be manufactured using a semiconductor process optimized for power transistor implementation. These semiconductor processes optimized for power transistor implementation may use a vertical transistor structure, wherein the transistor drain-source terminals are arranged on opposite sides of the transistor die. It may be beneficial for high-voltage power transistor implementation but probably not for advanced analog and digital circuits, preferably designed for low power consumption. Moreover, power transistors may benefit from a possible implementation using high electron mobility materials such as GaN or SiC. Semiconductor processes based on such materials may be not well suited for implementation of p-type transistors, which may be required for implementing digital logic circuits using complementary metal-oxide-semiconductor (CMOS) technology.

The second semiconductor die may be of a technology for implementing at least one external GaN FET and/or at least one external vertical power MOSFET. The at least one external switch-segment may comprise at least one external GaN FET and/or at least one external vertical power MOSFET. GaN FET is a field-effect transistor fabricated with GaN technology. GaN FETs offer several advantages over traditional silicon-based FETs, particularly in high-power and high-frequency applications. GaN FETs can be fabricated on different substrates, including silicon (GaN-on-silicon) or silicon carbide (GaN-on-SiC). The second semiconductor die may comprise at least one GaN-on-silicon-based external switch-segment. GaN-on-silicon may offer cost advantages due to compatibility with existing silicon manufacturing infrastructure, while GaN-on-SiC offers superior thermal conductivity and higher breakdown voltage capabilities. Vertical power MOSFETs may be a type of power transistor which may have a vertical structure. They can be designed with multiple layers of semiconductor material and feature a vertical current flow path. The second semiconductor die may comprise channel region oriented perpendicular to the substrate surface. Vertical power MOSFETs can specifically be designed to handle high voltages and high currents. They may be suitable for power electronics applications that may require efficient power switching and control.

The second semiconductor die may comprise at least one GaN-on-silicon (GaN-on-Si) based external switch-segment. GaN has a wider bandgap compared to traditional silicon, which allows for higher voltage operation, higher breakdown voltages, and higher operating temperatures. This may make GaN-on-silicon devices suitable for high-power and high-frequency applications.

The first semiconductor die may be of a MOS and/or Bipolar-CMOS-DMOS technology, preferably manufactured with lateral integration. A lateral, or horizontal, integration may refer to the capability of integrating different components or devices within the same plane or layer of the semiconductor substrate. It can involve the placement of devices side by side in a two-dimensional layout, allowing for compact and efficient circuit designs. Lateral integration may also refer to the integration of various transistors and passive components within a single layer of the semiconductor material. This integration can be achieved by utilizing the planar nature of the MOS process, where devices can be fabricated on the surface of the substrate.

In one embodiment, the second semiconductor die is of a direct bandgap semiconductor technology, such as a Gallium nitride technology. In a direct bandgap semiconductor technology, the minimum energy point of the conduction band (where electrons are excited to when conducting current) can align with the maximum energy point of the valence band (where electrons reside when not conducting current) at the same momentum in the electronic band structure. Direct bandgap semiconductor technologies may comprise Indium Phosphide (InP), Gallium Arsenide (GaAs), or Aluminium Gallium Nitride (AlGaN).

The second semiconductor die may be adapted for power transistor implementation. The second semiconductor die can preferably be manufactured with a semiconductor manufacturing process that can be adapted for more effective power transistor implementation. The adapted process can incorporate doping and diffusion steps to introduce specific dopants into the semiconductor material for e.g. implementing super-junction and/or double diffused MOSFETs. This customization of dopant profiles may be advantageous for achieving the desired conductivity and performance characteristics of power transistors. Moreover, a bipolar-CMOS-DMOS (BCD) semiconductor manufacturing process can implement both analog, digital and power transistors. Advantageously, to effectively implement power transistors, a dedicated BCD process can be chosen, which may preferably include the necessary process steps and lithography masks specific to power transistor devices. This selective approach can avoid the inclusion of process steps and lithography masks that may be needed for implementing digital low-voltage transistors. One notable advantage of the BCD process can be its cost-effectiveness in manufacturing power transistors. By utilizing only the essential process steps and masks required for producing semiconductor dies, it can ensure an efficient use of resources.

In another embodiment, the first semiconductor die is a silicon-based semiconductor die. A silicon-based semiconductor die may refer to a die made primarily from silicon.

The first semiconductor die may be composed of silicon. Silicon may offer excellent electrical properties, such as its ability to act as a semiconductor by controlling the flow of current. A die may be an individual unit that can be separated from the larger wafer on which it may be processed, and can function as a standalone electronic component.

A plurality of the power switches can be segmented switches, comprising at least one internal switch-segment disposed on a first semiconductor die manufactured with a first material composition and at least one external switch-segment disposed on a second semiconductor die manufactured with a second material composition different to the first material composition. Preferably, in the context of semiconductors, a material composition may refer to the specific combination or mixture of elements used to create a semiconductor material. The material composition can determine the properties and characteristics of the semiconductor, including its electrical conductivity, bandgap energy, carrier mobility, and thermal properties. Semiconductor material compositions can be typically expressed using chemical formulas or notations that may indicate the elements present in the material and their proportions. These compositions can be represented in different ways, depending on the specific semiconductor material system being discussed. The specific combination of elements and their proportions in a semiconductor material composition can affect its electrical properties. By adjusting the material composition, semiconductor properties can be tailored to meet specific requirements for various applications, such as power electronics or integrated circuits.

GaN transistors can cause EMI issues due to their high switching speeds. I.e. when the GaN transistor is turned on, the rapid increase in drain-source current (high di/dt) may cause high dv/dt on the converter's switching nodes. By using segmented switches, where at least one of the segments is a GaN transistor, and another segment is a silicon-based transistor having a higher channel-resistance than the GaN-based segment, the EMI issue can be alleviated. Accordingly, at least one internal switch-segment is silicon-based transistor and at least one external switch-segment is GaN-based. By turning ON the silicon-based segment with higher channel-resistance slightly before turning ON the GaN-based segment the dv/dt can be reduced and thereby reducing the EMI issues of the converter while still getting the advantage of the low channel-resistance of the GaN transistor. Furthermore, the lower dv/dt of the power stage switching nodes will reduce the Miller kick-back effect of the power switches that are OFF in a given switching state. A high dv/dt on the switch node can cause current injection through the drain-gate capacitance, which can cause the transistor to turn ON in a so-called spurious turn-on event. This is highly undesirable as it can dramatically increase the power loss and ultimately be destructive to the power transistor as it shorts part of the power stage.

Arranging power transistors on the second semiconductor die can provide multiple advantages. The power transistors may be subject to large thermal dissipation and this would affect the temperature sensitive circuitry arranged on the first semiconductor die if they would be placed on the same semiconductor die. A higher temperature may decrease the conductivity of the gate drivers, which would lead to a worse driving strength, therefore a potentially higher power consumption of the switched-capacitor DC-DC converter. Therefore, by having the gate drivers on the first semiconductor die and the power transistors on the second semiconductor die, this would benefit the overall power consumption and the performance of the switched-capacitor DC-DC converter. In another embodiment, at least one of the plurality of power switches has the positive terminal connected to a first flying capacitor of the plurality of flying capacitors and the negative terminal connected to a second flying capacitor of the plurality of flying capacitors. By having at least one of the plurality of power switches in the configuration previously described, the internal and/or potentially the external switch-segments of the at least one of the plurality of power switches may allow a control over a potential discharge of internal low-impedance nodes in the switched-capacitor DC-DC converter. This can limit the inrush currents in the internal nodes of the switched-capacitor DC-DC converter, therefore potentially improving reliability.

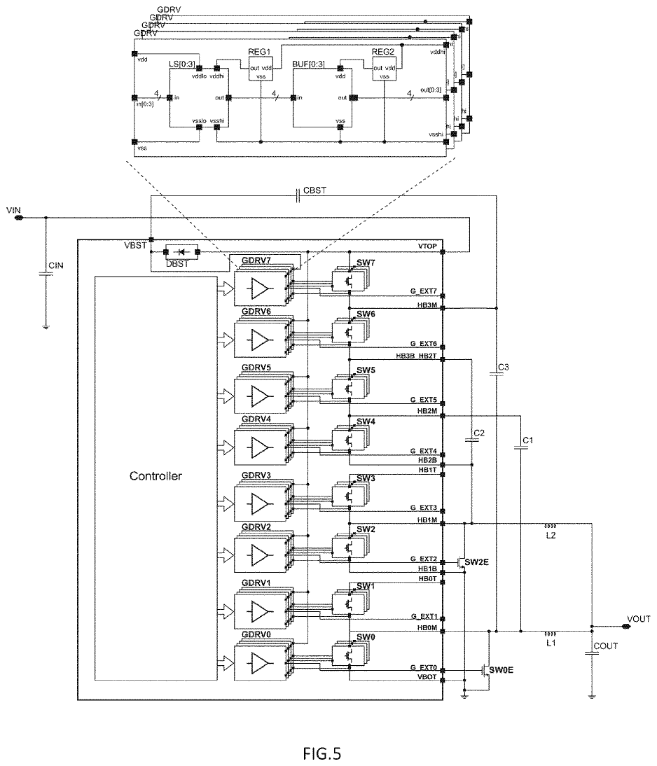

FIG. 5 shows a schematic view of an embodiment of a gate driver. The gate driver comprises a level shifter, a buffer and at least one linear voltage regulator. At least two of the plurality of gate drivers can be directly supplied from the DC input voltage. This may allow a gentle and controlled start-up of the switched-capacitor DC-DC converter. The at least two of the plurality of gate drivers may further comprise an internal linear voltage regulator. The internal linear voltage regulator is configured to provide the right supply voltage to the gate drivers by converting the DC input voltage of the switched-capacitor DC-DC converter to the appropriate gate driver DC supply voltage.

The plurality of gate drivers have a floating ground terminal from either the positive terminal or the negative terminal of the plurality of power switches. As shown in FIG. 1 or FIG. 2, the plurality of gate drivers have a floating ground which is following the voltage from the positive or the negative terminal of the plurality of power switches that they drive. This allows the gate driver to be supplied with the appropriate voltage, therefore preventing any voltages across the gate drivers being outside of the safe-operating area of the devices being used in the plurality of gate drivers. This may also allow the gate driver to drive the plurality of power switches with the appropriate voltage on the switches. More specifically, the plurality of gate drivers can deliver the right voltage to the gate of the internal and/or external switch-segments in order to correctly open or close the switch-segments.

In one embodiment, the switched-capacitor DC-DC converter further comprises at least one inductor connected in series with at least one of the flying capacitors. FIG. 2 shows two inductors L1 and L2, being connected in series with C2 and C1 or C3. This enables a hybrid configuration of a switched-capacitor DC-DC converter. This hybrid configuration may add some benefits to a switched-capacitor DC-DC converter without inductors, such as the ones previously described in the present disclosure. The at least one inductor has an inductance between 15 nH and 100 uH. In some low power applications, the capacitor may also be implemented on-chip together with the plurality of gate drivers using e.g. metal-oxide-metal, metal-insulator-metal or metal-oxide-semiconductor capacitor technologies. On-chip capacitor may have very low capacitance values, which makes them unsuited for high power applications, but the monolithic integration of the capacitors together with the plurality of gate drivers and the plurality of power switches can provide a very compact switched-capacitor DC-DC converter for low power applications. The switching frequency can be chosen to maximize the efficiency. A higher switching frequency can allow for transferring more energy through the plurality of flying capacitors per unit time. However, a higher switching frequency may also increase the dynamic switching and parasitic losses, which can increase the power dissipation. Furthermore, parasitic inductance in the plurality of flying capacitors charging/discharging loops can increase the impedance of these loops at higher frequencies.

A control unit may further be comprised in the switched-capacitor DC-DC converter. The control unit can be designed in order to provide the required control signals to the plurality of gate drivers. These control signals can be clocked, pseudo-random, or random, depending on the targeted application. The control unit can provide a clock with a specific frequency, depending on the configuration of the switched-capacitor DC-DC converter.

The control unit further comprises a clock controller and a serial communication bus. The clock controller can provide various clock signals, with different clock frequencies and/or phases. The serial communication bus may allow a secondary system communicating with the switched-capacitor DC-DC converter. This may also allow a system or a user to program the switched-capacitor DC-DC converter accordingly. The system may comprise a microcontroller or any other suitable microcomputer or processing unit for programming and/or controlling the switched-capacitor DC-DC converter.

The serial communication bus may be an inter-integrated circuits (I2C) serial bus protocol, a serial peripheral interface (SPI) serial bus protocol, system management bus (SMBus), power management bus (PMBus), adaptive voltage scaling bus (AVSBus) or a USB protocol. With a serial communication bus, data bits are transmitted one at a time in a sequential manner over the data bus or communication channel. Parallel communication may also be used, such as Small Computer System Interface (SCSI) or Peripheral Component Interconnect (PCI). Serial communication is generally preferred because of the multiple drawbacks inherent to the architecture of the parallel communication, such as crosstalk, number of cables used or possible clock skews. However, a parallel interface may still be used for static configuration of the chip, such as selecting the serial address of the chip or setting a certain fixed operating mode.

In another aspect, a programmable switch array for switched-capacitor DC-DC converter is disclosed. The programmable switch array for switched-capacitor DC-DC may comprise at least one input terminal, at least one output terminal, a plurality of power switches and a plurality of flying capacitor terminals connectable to a plurality of flying capacitors configured to convert a DC input voltage from the at least one input terminal to a DC output voltage to the at least one output terminal by a switched-capacitor power conversion. The at least one of the plurality of power switches is a segmented switch, comprising at least one internal switch-segment disposed on a first semiconductor die, and at least one switch-segment terminal connectable to at least one external switch-segment disposed on a second semiconductor die. A plurality of gate drivers may be configured to drive the plurality of power switches.

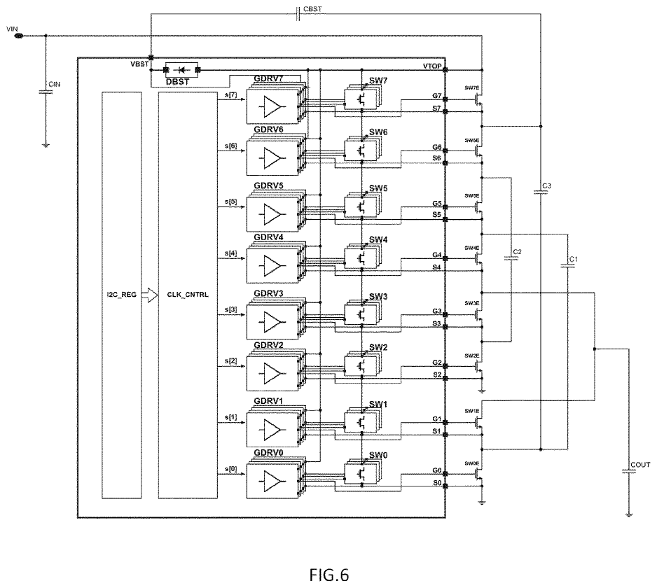

FIG. 6 shows a schematic view of an embodiment of a programmable switch array for switched-capacitor DC-DC converter, wherein the plurality of power switches is a segmented switch, but where at least one switch-segment is an external switch-segment, which is disposed on a second semiconductor die. A plurality of flying capacitors terminals are connectable to a plurality of flying capacitors, C1-C3, configured to convert a DC input voltage from the at least one input terminal to a DC output voltage to the at least one output terminal by a switched-capacitor power conversion. The at least one input terminal is named VTOP, which corresponds to the DC input voltage of the programmable switch array switched-capacitor DC-DC converter, and the at least one output terminal is named S4, which corresponds to the DC output voltage of the programmable switch array. The programmable switch array further comprises a plurality of gate drivers, such as GDRV0-GDRV7, which are configured to independently drive the plurality of power switches, such as SW0-SW7, as well as at least one switch-segment terminal connectable to at least one external switch-segment, such as SW0E-SW7E. GDRV0-GDRV7 comprises four independent gate drivers, wherein each of the gate drivers drives the at least one internal switch-segment disposed on the same die as the programmable switch array and the at least one external switch-segment. For instance, GDRV7 comprises four independent gate drivers, wherein three gate drivers drives the three internal switch-segments, comprised in the power switch SW7, and one external switch-segment terminal, which drives the external switch-segment SW7E through the terminal G7. The plurality of gate drivers are controlled from the unit CLK_CNTRL which delivers control signals s[0]-s[7] to the plurality of gate drivers GDRV0-GDRV7. A bootstrap circuit can be implemented to provide a boosted voltage for the top-most gate driver GDRV7. The bootstrap circuit comprises a bootstrap capacitor, named CBST, being arranged outside of the programmable switch array, and connected to the programmable switch array through the terminals VTOP and VBST, and a bootstrap diode, DBST. The top-most gate driver, GDRV7, may require a positive supply voltage, which cannot be provided by connecting the GDRV7 positive supply terminal to VTOP and the GDRV7 negative supply terminal to the source terminal of SW7 as the voltage from VTOP to the source of SW7 is approximately zero when SW7 is conducting. The bootstrap diode may provide a charging path from VTOP to the CBST boost capacitor when SW7 is opened (OFF) and the diode is blocking when SW7 is closed (ON). The result of the bootstrap circuit operation is a stable supply voltage for GDRV7 relative to the GDRV7 negative supply terminal, which is connected to the source terminal of SW7. A decoupling capacitor COUT is connected to the at least one output terminal to filter the DC output voltage of the programmable switch array and a decoupling capacitor CIN is connected to the at least one input terminal to filter the DC input voltage of the programmable switch array.

The plurality of gate drivers can have a plurality of terminals connectable to the at least one external switch-segment. The plurality of gate drivers may have the same characteristics as the ones previously described in the present disclosure.

The plurality of terminals comprises at least one switch terminal. The at least one switch terminal may be used to control the switching state of the at least one external switch-segment. The switching state of the at least one external switch-segment may be configured in multiple states, but preferably either opened or closed, or more generally called ON or OFF.

In another aspect, a method for performing a switched-capacitor DC-DC conversion comprises the following steps providing a switched-capacitor DC-DC converter comprising at least one input terminal, at least one output terminal, a plurality of power switches and a plurality of flying capacitors configured to convert a DC input voltage from the at least one input terminal to a DC output voltage to the at least one output terminal by a switched-capacitor power conversion, wherein at least one of the plurality of power switches is a segmented switch, comprising at least one internal switch-segment disposed on a first semiconductor die and at least one external switch-segment disposed on a second semiconductor die and a plurality of gate drivers configured to drive the plurality of power switches and performing a switched-capacitor DC-DC conversion by switching the plurality of power switches, using the at least one internal switch-segments and the at least one external switch-segment in order to convert a DC input voltage to a DC output voltage.

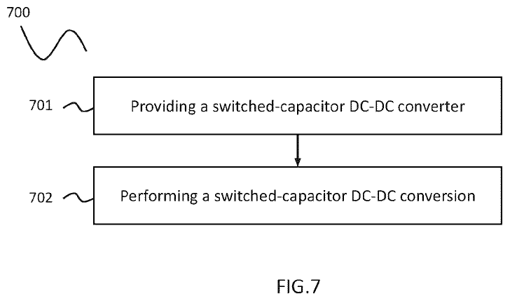

FIG. 7 shows a flow-chart of the presently disclosed method of performing a switched-capacitor DC-DC conversion (700). The method for performing a switched-capacitor DC-DC conversion comprises the following steps, which are providing a switched-capacitor DC-DC converter (701) and performing a switched-capacitor DC-DC conversion (702). FIG. 7 shows a flow-chart of the presently disclosed method and described in the previous paragraphs.

Further details of the invention
1. A switched-capacitor DC-DC converter comprising:
   at least one input terminal;
   at least one output terminal;
   a plurality of power switches and a plurality of flying capacitors configured to convert a DC input voltage from the at least one input terminal to a DC output voltage to the at least one output terminal by a switched-capacitor power conversion, wherein at least one of the plurality of power switches is a segmented switch, comprising at least one internal switch-segment disposed on a first semiconductor die and at least one external switch-segment disposed on a second semiconductor die; and
   a plurality of gate drivers configured to drive the plurality of power switches.
2. The switched-capacitor DC-DC converter according to item 1, wherein the DC input voltage is between 12 and 400 V, preferably between 36 and 60 V.
3. The switched-capacitor DC-DC converter according to any one of the preceding items, wherein the plurality of power switches and the plurality of flying capacitors are configured to perform a power conversion in a Dickson 1/4 or Ladder 1/5 or Dickson 1/6 configuration.
4. The switched-capacitor DC-DC converter according to any one of the preceding items, wherein the at least one internal switch-segment and the at least one external switch-segment are independently controlled by the plurality of gate drivers.
5. The switched-capacitor DC-DC converter according to any one of the preceding items, wherein the at least one internal switch-segment and/or the at least one external switch-segment are connected in parallel.
6. The switched-capacitor DC-DC converter according to any one of the preceding items, wherein the plurality of gate drivers are disposed on the first semiconductor die.
7. The switched-capacitor DC-DC converter according to any one of the preceding items, wherein the switched-capacitor DC-DC converter further comprises at least one secondary external switch-segment disposed on a third semiconductor die.
8. The switched-capacitor DC-DC converter according to any one of the preceding items, wherein each of the plurality of power switches have a positive terminal, such as a drain terminal, and a negative terminal, such as a source terminal.
9. The switched-capacitor DC-DC converter according to any one of the preceding items, wherein the at least one internal switch-segment comprises at least one field-effect transistor, preferably at least one metal-oxide-semiconductor field-effect transistor.
10. The switched-capacitor DC-DC converter according to item 9, wherein the at least one field-effect transistor is not a stacked or cascaded field-effect transistor.
11. The switched-capacitor DC-DC converter according to any one of items 9 to 10, wherein the at least one field-effect transistor is a high-voltage transistor, with a blocking voltage preferably equal or higher to the DC input voltage.
12. The switched-capacitor DC-DC converter according to any one of items 9 to 11, wherein the at least one field-effect transistor is a N-type transistor.
13. The switched-capacitor DC-DC converter according to any one of items 9 to 12, wherein the at least one field-effect transistor is an asymmetrical transistor type.
14. The switched-capacitor DC-DC converter according to item 13, wherein the asymmetrical transistor type have a maximum drain-source voltage (Vds) higher than the maximum gate-source voltage (Vgs).
15. The switched-capacitor DC-DC converter according to any one of the preceding items, wherein the at least one internal switch-segment is implemented on a silicon substrate.
16. The switched-capacitor DC-DC converter according to any one of the preceding items, wherein the at least one external switch-segment is at least one high electron mobility transistor.
17. The switched-capacitor DC-DC converter according to item 16, wherein the at least one high electron mobility transistor is at least one gallium nitride transistor.
18. The switched-capacitor DC-DC converter according to any one of the preceding items, wherein the first semiconductor die is configured for advanced analog and digital circuitry.
19. The switched-capacitor DC-DC converter according to any one of the preceding items, wherein the second semiconductor die is configured for power transistor implementation.
20. The switched-capacitor DC-DC converter according to any one of the preceding items, wherein at least two of the plurality of gate drivers are supplied from the DC input voltage.
21. The switched-capacitor DC-DC converter according to any one of the preceding items, wherein at least one of the plurality of power switches has the positive terminal connected to a first flying capacitor of the plurality of flying capacitors and the negative terminal to a second flying capacitor of the plurality of flying capacitors.
22. The switched-capacitor DC-DC converter according to any one of the preceding items, wherein the plurality of gate drivers have a floating ground terminal supplied from either the positive terminal or the negative terminal of the plurality of power switches.
23. The switched-capacitor DC-DC converter according to any one of the preceding items, wherein the at least two of the plurality of gate drivers further comprises a linear voltage regulator supplied from the DC input voltage.
24. The switched-capacitor DC-DC converter according to any one of the preceding items, further comprising at least one inductor connected in series with at least one of the plurality of flying capacitors.
25. The switched-capacitor DC-DC converter according to any one of the preceding items, wherein the at least one inductor have an inductance between 15 nH and 100 uH.
26. The switched-capacitor DC-DC converter according to any one of the preceding items, wherein the plurality of flying capacitors have a capacitance between 100 nF and 100 uF, preferably between 500 nF and 30 uF.
27. The switched-capacitor DC-DC converter according to any one of the preceding items, further comprising a control unit.
28. The switched-capacitor DC-DC converter according to item 27, wherein the control unit comprises a clock controller and a serial communication bus.
29. The switched-capacitor DC-DC converter according to item 28, wherein the serial communication bus is an I2C serial bus.
30. A programmable switch array for a switched-capacitor DC-DC converter comprising:
   at least one input terminal;
   at least one output terminal;
   a plurality of power switches and a plurality of flying capacitor terminals connectable to a plurality of flying capacitors configured to convert a DC input voltage from the at least one input terminal to a DC output voltage to the at least one output terminal by a switched-capacitor power conversion, wherein at least one of the plurality of power switches is a segmented switch, comprising at least one internal switch-segment disposed on a first semiconductor die, and at least one switch-segment terminal connectable to at least one external switch-segment disposed on a second semiconductor die; and
   a plurality of gate drivers configured to drive the plurality of power switches.
31. The programmable switch array for a switched-capacitor DC-DC converter according to item 30, wherein the plurality of gate drivers have a plurality of terminals connectable to the at least one external switch-segment.
32. The programmable switch array for a switched-capacitor DC-DC converter according to any one of items 30 to 31, wherein the plurality of terminals comprise at least one switch terminal.
33. The programmable switch array for a switched-capacitor DC-DC converter according to any one of items 30 to 32, wherein the at least one switch terminal controls a switching state of the at least one external switch-segment.
34. A method for performing a switched-capacitor DC-DC conversion comprising the following steps:
   providing a switched-capacitor DC-DC converter comprising:
      at least one input terminal;
      at least one output terminal;
      a plurality of power switches and a plurality of flying capacitors configured to convert a DC input voltage from the at least one input terminal to a DC output voltage to the at least one output terminal by a switched-capacitor power conversion, wherein at least one of the plurality of power switches is a segmented switch, comprising at least one internal switch-segment disposed on a first semiconductor die and at least one external switch-segment disposed on a second semiconductor die; and
      a plurality of gate drivers configured to drive the plurality of power switches; and
performing a switched-capacitor DC-DC conversion by switching the plurality of power switches, using the at least one internal switch-segment and the at least one external switch-segment in order to convert a DC input voltage to a DC output voltage.
35. The method for performing a switched-capacitor DC-DC conversion according to item 34, wherein the switched-capacitor DC-DC converter is the switched-capacitor DC-DC converter according to any one of items 1-29.

1-25. (canceled)

26. A switched-capacitor DC-DC converter comprising:
at least one input terminal;
at least one output terminal;
a plurality of power switches and a plurality of flying capacitors configured to convert a DC input voltage from the at least one input terminal to a DC output voltage to the at least one output terminal by a switched-capacitor power conversion, wherein at least one of the plurality of power switches is a segmented switch, comprising at least one internal switch-segment disposed on a first semiconductor die of a first semiconductor manufacturing technology and at least one external switch-segment disposed on a second semiconductor die of a second semiconductor manufacturing technology different to the first semiconductor manufacturing technology; and
a plurality of gate drivers configured to drive the plurality of power switches.

27. The switched-capacitor DC-DC converter of claim 26, wherein the second semiconductor die is of a technology for implementing at least one external GaN FET and/or at least one external vertical power MOSFET.

28. The switched-capacitor DC-DC converter of claim 26, wherein the at least one external switch-segment comprises at least one external GaN FET and/or at least one external vertical power MOSFET.

29. The switched-capacitor DC-DC converter of claim 26, wherein the second semiconductor die comprises at least one GaN-on-silicon-based external switch-segment.

30. The switched-capacitor DC-DC converter of claim 26, wherein the first semiconductor die is of a MOS and/or Bipolar-CMOS-DMOS technology, preferably manufactured with lateral integration.

31. The switched-capacitor DC-DC converter of claim 26, wherein the second semiconductor die is of a direct bandgap semiconductor technology, such as a Gallium nitride technology.

32. The switched-capacitor DC-DC converter of claim 26, wherein the second semiconductor die is adapted for power transistor implementation or wherein the first semiconductor die is a silicon-based semiconductor die.

33. The switched-capacitor DC-DC converter of claim 26, wherein at least one internal switch-segment comprises a MOS and/or Bipolar-CMOS-DMOS-based transistor and wherein at least one external switch-segment comprises a GaN FET and/or an external vertical power MOSFET.

34. The switched-capacitor DC-DC converter of claim 26, wherein at least one internal switch-segment is silicon-based transistor and at least one external switch-segment is GaN-based.

35. The switched-capacitor DC-DC converter of claim 26, wherein a plurality of the power switches are segmented switches, comprising at least one internal switch-segment disposed on a first semiconductor die manufactured with a first material composition and at least one external switch-segment disposed on a second semiconductor die manufactured with a second material composition different to the first material composition.

36. The switched-capacitor DC-DC converter of claim 26, wherein the at least one internal switch-segment and the at least one external switch-segment are independently controlled by the plurality of gate drivers.

37. The switched-capacitor DC-DC converter of claim 26, wherein the at least one internal switch-segment and/or the at least one external switch-segment are connected in parallel.

38. The switched-capacitor DC-DC converter of claim 26, wherein the plurality of gate drivers are disposed on the first semiconductor die.

39. The switched-capacitor DC-DC converter of claim 26, wherein the switched-capacitor DC-DC converter further comprises at least one secondary external switch-segment disposed on a third semiconductor die.

40. The switched-capacitor DC-DC converter of claim 26, wherein the at least one internal switch-segment comprises at least one field-effect transistor, preferably at least one metal-oxide-semiconductor field-effect transistor, and wherein the at least one field-effect transistor is not stacked or cascaded field-effect transistor.

41. The switched-capacitor DC-DC converter of claim 26, wherein the at least one field-effect transistor is a high-voltage transistor, with a blocking voltage equal or higher to the DC input voltage.

42. The switched-capacitor DC-DC converter of claim 26, wherein the at least one external switch-segment is at least one high electron mobility transistor.

43. The switched-capacitor DC-DC converter of claim 26, wherein at least two of the plurality of gate drivers are supplied from the DC input voltage.

44. A programmable switch array for a switched-capacitor DC-DC converter comprising:
at least one input terminal;
at least one output terminal;
a plurality of power switches and a plurality of flying capacitor terminals connectable to a plurality of flying capacitors configured to convert a DC input voltage from the at least one input terminal to a DC output voltage to the at least one output terminal by a switched-capacitor power conversion, wherein at least one of the plurality of power switches is a segmented switch, comprising at least one internal switch-segment disposed on a first semiconductor die of a first semiconductor manufacturing technology, and at least one switch-segment terminal connectable to at least one external switch-segment disposed on a second semiconductor die of a second semiconductor manufacturing technology different to the first semiconductor manufacturing technology; and
a plurality of gate drivers configured to drive the plurality of power switches.

45. A method for performing a switched-capacitor DC-DC conversion comprising the following steps:
providing a switched-capacitor DC-DC converter comprising:
at least one input terminal;
at least one output terminal;
a plurality of power switches and a plurality of flying capacitors configured to convert a DC input voltage from the at least one input terminal to a DC output voltage to the at least one output terminal by a switched-capacitor power conversion, wherein at least one of the plurality of power switches is a segmented switch, comprising at least one internal switch-segment disposed on a first semiconductor die of a first semiconductor manufacturing technology, and at least one external switch-segment disposed on a second semiconductor die of a second semiconductor manufacturing technology different to the first semiconductor manufacturing technology; and
a plurality of gate drivers configured to drive the plurality of power switches; and
performing a switched-capacitor DC-DC conversion by switching the plurality of power switches, using the at least one internal switch-segment and the at least one external switch-segment in order to convert a DC input voltage to a DC output voltage.
